(19) United States
(12) Patent Application Publication
(10) Pub. No.: US 2024/0371606 A1
(43) Pub. Date: Nov. 7, 2024

(54) PLASMA FILM FORMING APPARATUS AND PLASMA FILM FORMING METHOD

(71) Applicant: Tokyo Electron Limited, Tokyo (JP)

(72) Inventors: Atsuki FUKAZAWA, Tokyo (JP); Hiroki MAEHARA, Tokyo (JP)

(21) Appl. No.: 18/777,099

(22) Filed: Jul. 18, 2024

Related U.S. Application Data
(63) Continuation of application No. PCT/JP2022/043672, filed on Nov. 28, 2022.

(30) Foreign Application Priority Data
Jan. 19, 2022 (JP) 2022-006380

(51) Int. Cl. H01J 37/32; C23C 16/455; C23C 16/50

(52) U.S. Cl. CPC H01J 37/3244; C23C 16/45563; C23C 16/50; H01J 2237/332

(57) ABSTRACT

A technique for performing local film formation at a desired position on a substrate by using plasma is provided. A plasma film forming apparatus includes a chamber, a substrate support configured to support a substrate in the chamber, a first nozzle configured to supply first gas that is formed into plasma to a region on the substrate support, a second nozzle configured to supply second gas that reacts with the first gas into the chamber, in which the first gas reacts with the second gas in the chamber to form a film at a predetermined position on the substrate supported by the substrate support, and a mover configured to move the second nozzle relatively to the substrate support, in which the predetermined position is determined based on a position of the second nozzle relative to the substrate support.

### CROSS-REFERENCE TO RELATED APPLICATIONS

This application is a bypass continuation application of international application No. PCT/JP2022/043672 having an international filing date of Nov. 28, 2022 and designating the United States, the international application being based upon and claiming the benefit of priority from Japanese Patent Application No. 2022-006380, filed on Jan. 19, 2022, the entire contents of which are incorporated herein by reference.

### TECHNICAL FIELD

Exemplary embodiments of the present disclosure relate to a plasma film forming apparatus and a plasma film forming method.

### BACKGROUND

JP2004-183071A discloses a technique for preventing pulsations of plasma when a processing gas is formed into the plasma to form a film.

### SUMMARY

One exemplary embodiment of the present disclosure provides a plasma film forming apparatus including: a chamber; a substrate support configured to support a substrate in the chamber; a first nozzle configured to supply first gas that is formed into plasma to a region on the substrate support; a second nozzle configured to supply second gas that reacts with the first gas into the chamber, in which the first gas reacts with the second gas in the chamber to form a film at a predetermined position on the substrate supported by the substrate support; and a mover configured to move the second nozzle relatively to the substrate support, in which the predetermined position is determined based on a position of the second nozzle relative to the substrate support.

### BRIEF DESCRIPTION OF DRAWINGS

FIG. 1 is a view schematically illustrating an example of a configuration of a plasma film forming apparatus.

FIG. 2 is a view illustrating an example of a configuration of a plasma film forming apparatus in which an inside of a chamber is seen in a plan view.

FIG. 3 is a flowchart illustrating an example of main steps of a present plasma film forming method.

FIG. 4A is a view illustrating a state where a film is formed at a center of a substrate.

FIG. 4B is a view illustrating a state where the film is diffused on an entire surface of the substrate.

FIG. 4C is a view illustrating a state where a position at which the film is formed on the substrate is changed.

FIG. 5 is a plan view illustrating an example of an operation when the position at which the film is formed on the substrate is changed.

FIG. 6A is a view illustrating an example in which a film thickness varies in a substrate surface.

FIG. 6B is a view illustrating an example in which the film thickness varies in the substrate surface.

FIG. 7 is a view illustrating an example in which the film is partially formed on the substrate.

FIG. 8 is a view illustrating an example in which the film is formed in a groove on the substrate.

FIG. 9 is a view schematically illustrating an example of a configuration of the plasma film forming apparatus provided with a first nozzle having a plurality of ejection ports.

FIG. 10 is a plan view illustrating an example of the operation when the position at which the film is formed on the substrate is changed.

FIG. 11 is a view illustrating an example of the operation when the position at which the film is formed on the substrate is changed.

FIG. 12 is a view schematically illustrating an example of a configuration of the plasma film forming apparatus in which a substrate support can be moved in a horizontal direction.

FIG. 13 is a plan view illustrating an example of the operation when the position at which the film is formed on the substrate is changed.

FIG. 14 is a view schematically illustrating an example of a configuration of the plasma film forming apparatus in which a second nozzle is connected to the first nozzle.

FIG. 15 is a view illustrating an example in which a plurality of types of films are formed on the substrate.

### DETAILED DESCRIPTION

Hereinafter, embodiments of the present disclosure will be described.

In one exemplary embodiment, a plasma film forming apparatus includes a chamber, a substrate support configured to support a substrate in the chamber, a first nozzle configured to supply first gas that is formed into plasma to a region on the substrate support, a second nozzle configured to supply second gas that reacts with the first gas into the chamber, in which the first gas reacts with the second gas in the chamber to form a film at a predetermined position on the substrate supported by the substrate support, and a mover configured to move the second nozzle relatively to the substrate support, in which the predetermined position is determined based on a position of the second nozzle relative to the substrate support.

In one exemplary embodiment, the mover may have a moving mechanism configured to move the second nozzle above the substrate support.

In one exemplary embodiment, in which the first nozzle may have a plurality of ejection ports for ejecting the first gas toward the region on the substrate support, the second nozzle may have an ejection port for ejecting the second gas, and the mover may be configured to move the second nozzle to move the ejection ports of the second nozzle to a position at which ejection of the second gas to the first gas ejected from each ejection port of the first nozzle toward the region on the substrate support is enabled.

In one exemplary embodiment, a plasma film forming apparatus includes a chamber, a substrate support configured to support a substrate in the chamber, a first nozzle configured to supply first gas that is formed into plasma to a region on the substrate support, a second nozzle configured to supply second gas that reacts with the first gas into the first nozzle, in which the first gas reacts with the second gas to form a film at a predetermined position on the substrate supported by the substrate support, and a mover configured to relatively move the first nozzle and the substrate support, in which the predetermined position is determined based on a position of the first nozzle relative to the substrate support.

In one exemplary embodiment, the mover may have a moving mechanism configured to move the substrate support.

In one exemplary embodiment, the film formed on the substrate may be in a liquid state.

In one exemplary embodiment, a plasma film forming method is executed in a plasma film forming apparatus including a chamber, a substrate support configured to support a substrate in the chamber, a first nozzle configured to supply gas to a region on the substrate support, and a second nozzle configured to supply gas into the chamber, the plasma film forming method including (a) preparing the substrate on the substrate support, (b) adjusting a relative position between the second nozzle and the substrate support, (c) supplying, via the first nozzle, first gas that is formed into plasma to the substrate, and (d) supplying, via the second nozzle, second gas that reacts with the first gas into the chamber, in which the first gas reacts with the second gas in the chamber to form a film at a predetermined position on the substrate, in which the (b) includes adjusting the relative position between the second nozzle and the substrate support to determine the predetermined position.

In one exemplary embodiment, in the plasma film forming method, the first nozzle may have a plurality of ejection ports for ejecting the first gas toward the region on the substrate support, the second nozzle may have an ejection port for ejecting the second gas, and in the (b), the second nozzle may be moved to move the ejection port of the second nozzle to a position at which ejection of the second gas to the first gas ejected from the ejection port in any one ejection port among the plurality of ejection ports of the first nozzle toward the region on the substrate support is enabled, the first gas may react with the second gas above the substrate, and a reaction product of the first gas and the second gas may be deposited on the substrate to form the film on the substrate.

In one exemplary embodiment, a plasma film forming method is executed in a plasma film forming apparatus including a chamber, a substrate support configured to support a substrate in the chamber, a first nozzle configured to supply gas to a region on the substrate support, and a second nozzle configured to supply gas into the first nozzle, the plasma film forming method including (a) preparing the substrate on the substrate support, (b) adjusting a relative position between the first nozzle and the substrate support, (c) supplying, via the first nozzle, first gas that is formed into plasma to the substrate, and (d) supplying, via the second nozzle, second gas that reacts with the first gas into the first nozzle, in which the first gas reacts with the second gas to form a film at a predetermined position on the substrate, in which the (b) includes adjusting the relative position between the first nozzle and the substrate support to determine the predetermined position.

In one exemplary embodiment, the plasma film forming method may further include (e) supplying the first gas from the first nozzle to the region on the substrate support to post-process the film formed on the substrate.

In one exemplary embodiment, in the plasma film forming method, in the (d), a liquid-state film may be formed on the substrate.

Hereinafter, each embodiment of the present disclosure will be described in detail with reference to the drawings. In the drawings, the same or similar elements are denoted by the same reference numerals, and overlapping descriptions thereof will be omitted. Unless otherwise specified, a positional relationship of up/down, left/right, or the like will be described based on a positional relationship illustrated in the drawings. The dimensional ratios in the drawings do not indicate actual ratios, and the actual ratios are not limited to the illustrated ratios.

### First Exemplary Embodiment

### Exemplary Embodiment of Plasma Film Forming Apparatus

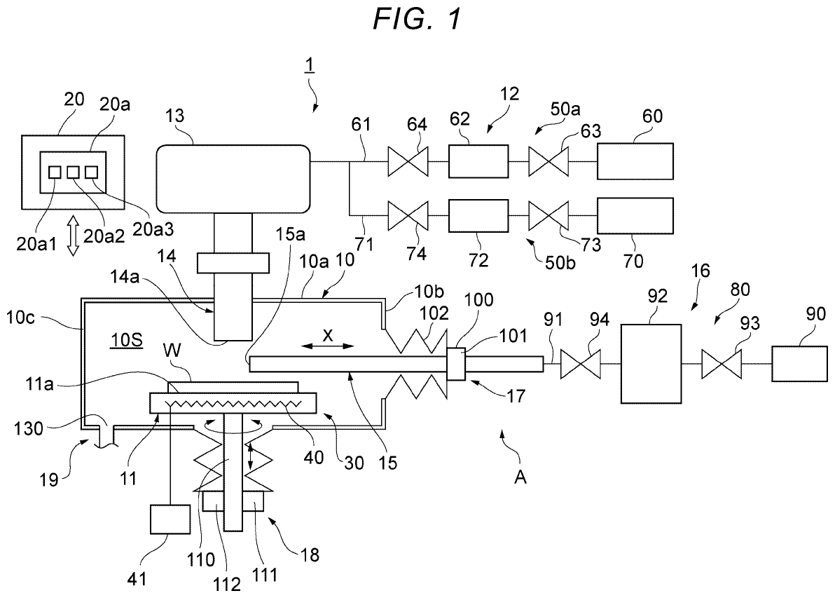

Hereinafter, a configuration example of a plasma film forming apparatus 1 will be described. FIG. 1 is a view illustrating an example of a configuration of the plasma film forming apparatus 1 of a remote plasma method. A plasma film forming method (hereinafter referred to as the “present plasma film forming method”) according to one exemplary embodiment is executed by using the plasma film forming apparatus 1.

In one embodiment, the plasma film forming apparatus 1 includes a plasma processing chamber (chamber) 10, a substrate support (susceptor) 11, a first gas supply 12, a remote plasma generation device 13, a first nozzle 14, a second nozzle 15, a second gas supply 16, a mover A (first moving mechanism 17 and second moving mechanism 18), an exhaust system 19, and a controller 20.

In one embodiment, the chamber 10 has a substantially cylindrical shape formed to be airtight.

In one embodiment, the substrate support 11 has a substantially disc shape that horizontally holds a substrate W. A wafer is an example of the substrate W. The substrate support 11 is located at the center of the chamber 10. The substrate support 11 has, on an upper surface thereof, a horizontal placement surface 11a on which the substrate W is placed. A processing space 10s for the substrate W is formed above the substrate support 11 in the chamber 10. The substrate support 11 includes an electrostatic chuck that electrostatically attracts the substrate W to the placement surface 11a.

In one embodiment, the substrate support 11 has a temperature controller 30. In one embodiment, the temperature controller 30 has a heater 40 embedded in the substrate support 11, and a heater power supply 41 that supplies power to the heater 40. The temperature controller 30 can warm the substrate support 11 by causing the heater 40 to generate heat via the heater power supply 41. In one embodiment, the temperature controller 30 has a coolant passage and a coolant supply device (not illustrated), and can cool the substrate support 11 by supplying the coolant to the coolant passage via the coolant supply device. The temperature controller 30 may include a Peltier element or the like as another temperature control member.

The substrate support 11 is provided with a lifter (lift pin) (not illustrated). In one embodiment, the lifter is disposed in each of a plurality of through-holes penetrating the substrate support 11 in an up-down direction, and is moved in the through-hole in the up-down direction by a driving device (not illustrated). In one embodiment, the substrate W is loaded into and out of the chamber 10 by a transport arm (not illustrated). The lifter can support and raise and lower the substrate W on the substrate support 11, exchange the substrate W with the transport arm, and place the substrate W on the substrate support 11.

In one embodiment, the first gas supply 12 has one or more gas introduction units. In one embodiment, the first gas supply 12 has two gas introduction units 50a and 50b. The first gas introduction unit 50a has a first source 60 of inert gas and an introduction path 61 through which the inert gas is introduced from the first source 60 into the remote plasma generation device 13. The introduction path 61 as an example includes a mass controller 62, a valve 63 on an upstream side of the mass controller 62, a valve 64 on a downstream side of the mass controller 62, and the like. The second gas introduction unit 50b has a second source 70 of reaction gas and an introduction path 71 through which the reaction gas is introduced from the second source 70 into the remote plasma generation device 13. The introduction path 71 as an example includes a mass controller 72, a valve 73 on an upstream side of the mass controller 72, a valve 74 on a downstream side of the mass controller 72, and the like.

The inert gas and the reaction gas are examples of first gas. The inert gas includes an Ar gas, a He gas, or the like. The reaction gas includes an oxidizing gas such as O₂, a reducing gas such as H₂, and a nitriding gas such as NH₃ or N₂ gas.

The remote plasma generation device 13 forms the introduced gas into plasma, to generate the first gas formed into the plasma. The first gas formed into the plasma contains radicals or ions.

In one embodiment, the first nozzle 14 is inserted into the chamber 10 by penetrating a ceiling wall 10a of the chamber 10 from the remote plasma generation device 13. The first nozzle 14 is fixed to the ceiling wall 10a of the chamber 10. The first nozzle 14 is a pipe extending in the up-down direction, and has, at a distal end thereof, an ejection port 14a directed toward the substrate support 11 on the lower side. In one embodiment, the ejection port 14a of the first nozzle 14 is directed toward the center of the substrate W held by the substrate support 11. In one embodiment, the ejection port 14a of the first nozzle 14 is disposed close to the placement surface 11a (substrate W) of the substrate support 11, and a distance from the ejection port 14a of the first nozzle 14 to the placement surface 11a of the substrate support 11 during a film formation process may be set to be about 20 mm or more and 50 mm or less.

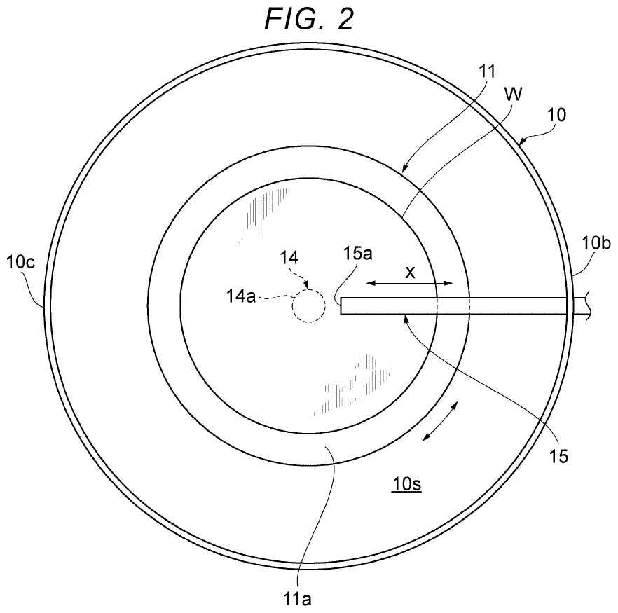

In one embodiment, the second nozzle 15 is inserted into the chamber 10 by penetrating a side wall 10b of the chamber 10 from the outside of the chamber 10. In one embodiment, the second nozzle 15 is a pipe extending in the horizontal direction, and has, at a distal end thereof, an ejection port 15a directed toward the center of the chamber 10 (the side wall 10c opposite to the chamber 10). A height of the ejection port 15a of the second nozzle 15 is slightly lower than a height of the ejection port 14a of the first nozzle 14. A difference between the height of the ejection port 15a of the second nozzle 15 (the height of the center position of the ejection port 15a in the up-down direction) and the height of the ejection port 14a of the first nozzle 14 may be set to about 20 mm or more and 30 mm or less. In one embodiment, as illustrated in FIG. 2, the second nozzle 15 and the ejection port 15a are located above a diameter of the substrate W held by the substrate support 11.

The second gas supply 16 illustrated in FIG. 1 has one or more gas introduction units. In one embodiment, the second gas supply 16 has one gas introduction unit 80. The gas introduction unit 80 has a third source 90 of raw material gas and an introduction path 91 through which the raw material gas is introduced from the third source 90 into the second nozzle 15. The introduction path 91 as an example includes a device 92 that includes a mass controller and a vaporizer, a valve 93 on an upstream side of the device 92, a valve 94 on a downstream side of the device 92, and the like. The raw material gas is gas as a raw material (precursor) for film formation, and is an example of second gas. The raw material gas includes silicon-containing gas. The silicon-containing gas includes an aminosilane-based gas, an alkylsilane-based gas, a silazane-silyl-based gas, a siloxane-based gas, and the like.

The mover A has a function of moving the second nozzle 15 relatively to the substrate support 11, and changing a predetermined position at which the film is formed on the substrate W on the substrate support 11, to an optional position on the substrate surface. In one embodiment, the mover A can move the second nozzle 15 to any position in the substrate surface. In one embodiment, the mover A includes a first moving mechanism 17 and a second moving mechanism 18. The first moving mechanism 17 has a function of moving the second nozzle 15 on the substrate W on the substrate support 11. In one embodiment, the first moving mechanism 17 has a nozzle holder 100 that holds the second nozzle 15, and a driver 101 that advances and retreats the nozzle holder 100 in a horizontal direction X. A contraction sealing member 102 that enables the movement of the second nozzle 15 with respect to the side wall 10b of the chamber 10 while maintaining the airtightness in the chamber 10 is provided between the side wall 10b of the chamber 10 and the second nozzle 15. The first moving mechanism 17 can move the ejection port 15a of the second nozzle 15 from at least a position above the center of the substrate W on the diameter of the substrate W on the substrate support 11 to a position above an outer edge.

In one embodiment, the second moving mechanism 18 has a function of rotationally moving the substrate support 11 and vertically moving the substrate support 11. In one embodiment, the second moving mechanism 18 includes a support 110 that supports the center of the substrate support 11 from below, and a driver 111 that rotates the support 110 around a vertical central axis. Further, the second moving mechanism 18 includes a driver 112 that vertically moves the support 110. The second moving mechanism 18 can rotate the substrate support 11 (the substrate W) with respect to the second nozzle 15. The second moving mechanism 18 can adjust a distance between the substrate support 11 (the substrate W), and the ejection ports 15a of the second nozzle 15 and the ejection ports 14a of the first nozzle 14.

The exhaust system 19 may be connected to a gas exhaust port 130 provided at a bottom of the chamber 10, for example. The exhaust system 19 may include a pressure adjusting valve and a vacuum pump. A pressure in the processing space 10s is adjusted by the pressure adjusting valve. The vacuum pump may include a turbo molecular pump, a dry pump, or a combination thereof.

The controller 20 processes computer-executable instructions for instructing the plasma film forming apparatus 1 to execute various steps described in the present disclosure. The controller 20 may be configured to control the respective elements of the plasma film forming apparatus 1 to execute the various steps described herein. In one embodiment, the controller 20 controls the operations of the gas introduction units 50a, 50b, and 80, the remote plasma generation device 13, the temperature controller 30, the first moving mechanism 17, the second moving mechanism 18, the exhaust system 19, and the like. In one embodiment, a part or all of the controller 20 may be included in the plasma film forming apparatus 1. The controller 20 may include, for example, a computer 20a. For example, the computer 20a may include a processor (central processing unit (CPU)) 20a1, a storage unit 20a2, and a communication interface 20a3. The processor 20a1 may be configured to read a program from the storage unit 20a2 and perform various control operations by executing the read program. The program may be stored in advance in the storage unit 20a2, or may be acquired via a medium when necessary. The acquired program is stored in the storage unit 20a2, and is read from the storage unit 20a2 and executed by the processor 20a1. The medium may be various storing media readable by the computer 20a, or may be a communication line connected to the communication interface 20a3. The storage unit 20a2 may include a random access memory (RAM), a read only memory (ROM), a hard disk drive (HDD), a solid state drive (SSD), or a combination thereof. The communication interface 20a3 may communicate with the plasma film forming apparatus 1 via a communication line such as a local area network (LAN).

### Exemplary Embodiment of Present Plasma Film Forming Method

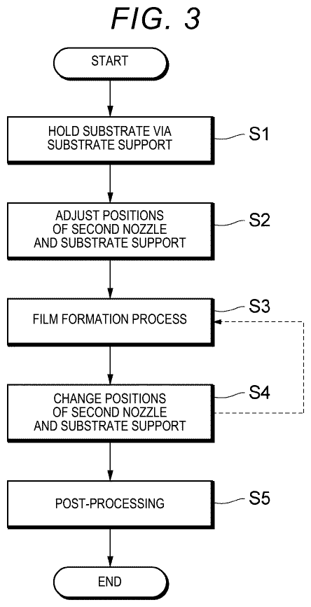

FIG. 3 is a flowchart illustrating the main steps of the present plasma film forming method executed in the plasma film forming apparatus 1.

First, in one embodiment, the substrate W is loaded into the chamber 10 by the transport arm, placed on the substrate support 11 by the lifter, and attracted and held by the substrate support 11. Accordingly, as illustrated in FIG. 1, the substrate W is supported (prepared) by the substrate support 11 (step S1 of FIG. 3).

Next, the relative position between the second nozzle 15 and the substrate support 11 is adjusted, and a forming position of the film on the substrate W on the substrate support 11 is adjusted (step S2 of FIG. 3). As an example, as illustrated in FIG. 1, the first moving mechanism 17 moves the second nozzle 15 such that the ejection port 15a is located above the vicinity of the center of the substrate W. Accordingly, the ejection port 15a of the second nozzle 15 is located in the vicinity immediately below the ejection port 14a of the first nozzle 14.

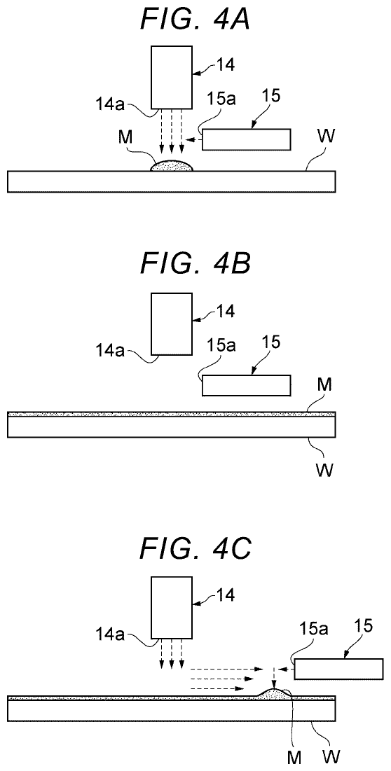

Next, a film formation process is performed (step S3 of FIG. 3). In one embodiment, the first gas consisting of the inert gas and the reaction gas is supplied from the first gas supply 12 to the remote plasma generation device 13. The first gas is formed into the plasma in the remote plasma generation device 13. The first gas formed into the plasma is introduced into the chamber 10 through the first nozzle 14, and ejected from the ejection port 14a (FIG. 4A). The first gas is ejected downward toward the substrate W on the substrate support 11. As an example, the first gas is supplied toward the center position of the substrate W. The exhaust system 19 operates, and the atmosphere in the chamber 10 is exhausted from the gas exhaust port 130.

The second gas consisting of the raw material gas is supplied from the second gas supply 16 to the second nozzle 15, introduced into the chamber 10 through the second nozzle 15, and ejected from the ejection port 15a. The second gas is supplied to the first gas flowing toward the center position of the substrate W (FIG. 4A). The second gas combines with and reacts with the first gas immediately above the center position of the substrate W, and a film M is formed at the center of the substrate W immediately below thereof. As an example, the temperature controller 30 controls the temperature of the substrate support 11 to a low temperature of about 0° C. or lower, so that a liquid film M is formed on the substrate W. As an example, the temperature controller 30 controls the temperature of the substrate support 11 to a high temperature of about 100° C. or higher, so that a bulk (solid) film M is formed on the substrate W. The first gas from the first nozzle 14 and the second gas from the second nozzle 15 are supplied for a predetermined time, and then the supply of the first gas and the second gas is stopped. A forming amount of the film M on the substrate W can be adjusted by a supply amount of the second gas from the second nozzle 15 or a supply amount of the first gas from the first nozzle 14.

Next, in one embodiment, the substrate support 11 is rotated by the second moving mechanism 18, and the substrate W is rotated around the central axis. The liquid film M at the center of the substrate W is spread over the entire surface of the substrate W (FIG. 4B). The rotation of the substrate W via the substrate support 11 is stopped, and the film formation process ends. Further, in a case where the film is a liquid or a solid, the film M may be formed only at the center of the substrate W without the rotation of the substrate support 11.

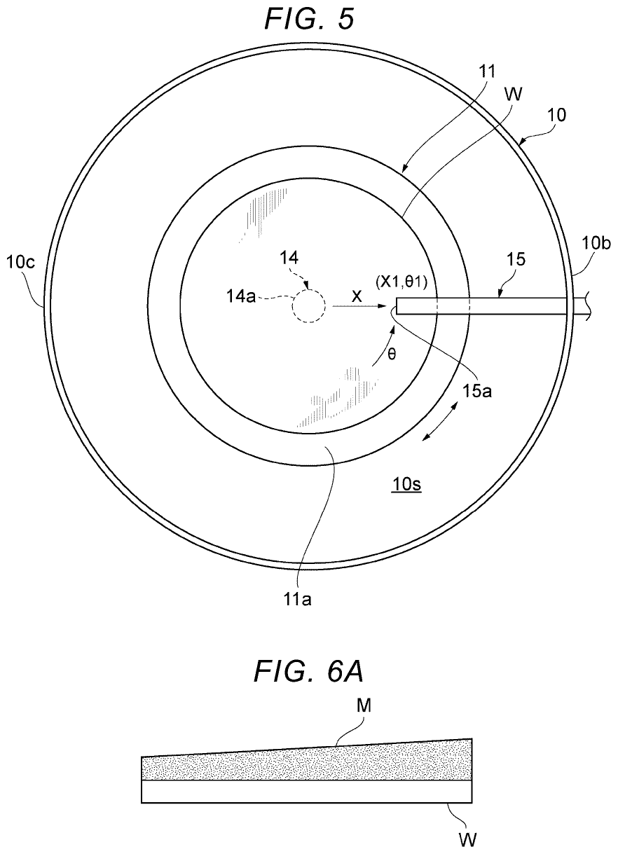

Next, the relative position between the second nozzle 15 and the substrate support 11 is changed, and the forming position of the film on the substrate W is changed (step S4 of FIG. 3). As an example, the first moving mechanism 17 moves the ejection port 15a of the second nozzle 15 from a position above the center of the substrate W to an outer peripheral side, and moves above a target position (x1) of the substrate W in the horizontal direction X, as illustrated in FIG. 5. Further, the substrate support 11 is rotated by the second moving mechanism 18, and a target position (θ1) of the substrate W in a circumferential direction θ is moved below the ejection port 15a of the second nozzle 15. As a result, the ejection port 15a of the second nozzle 15 moves to upper part of a target position (x1, θ1) on the substrate W. Then, as an example, the first gas is supplied from the ejection port 14a of the first nozzle 14 to the substrate W, and is diffused on the entire surface of the substrate W immediately above the substrate W, and the second gas is supplied from the ejection port 15a of the second nozzle 15 to the first gas immediately above the substrate W (FIG. 4C). As a result, the second gas reacts with the first gas, and the liquid or bulk film M is formed at the target position (x1, θ1) of the substrate W immediately below thereof. Thereafter, the supply of the first gas and the second gas is stopped. In this way, the predetermined position on the substrate W is partially refilled with the film M, and the in-surface distribution of the film formed on the substrate W is adjusted. Thereafter, the process may return to the film formation process (step S3) as necessary, and the film formation process (step S3) and the process of changing the relative position between the second nozzle 15 and the substrate support 11 (step S4) may be repeated one or more predetermined times.

Thereafter, post-processing of the film M of the substrate W is performed (step S5 of FIG. 3). As an example of the post-processing, the temperature controller 30 controls the temperature of the substrate support 11 to a high temperature of about 200° C., and the first gas formed into the plasma is supplied from the first nozzle 14 to the substrate W. In this case, the second nozzle 15 is retreated from above the substrate W, and the supply of the second gas is stopped. In this way, the composition of the film M on the substrate W is adjusted or the film M is cured. Thereafter, the supply of the first gas is stopped, the substrate W is unloaded from the chamber 10, and the present plasma film forming method ends.

According to the present exemplary embodiment, the plasma film forming apparatus 1 has the mover A that moves the second nozzle 15 relatively to the substrate support 11, and determines the predetermined position at which the film M is formed on the substrate W on the substrate support 11, based on the position of the second nozzle 15 relative to the substrate support 11. The first moving mechanism 17 and the second moving mechanism 18 are examples of the mover A. Accordingly, it is possible to perform local film formation at a desired position on the substrate W by using the plasma. Further, it is possible to perform partial control or in- surface control of the thickness of the film formed on the substrate W.

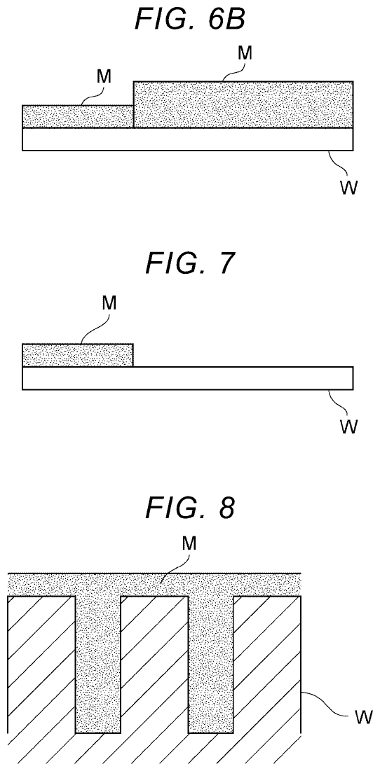

According to the present exemplary embodiment, the in-surface control of the film thickness can be performed while varying the thickness of the film M in the surface of the substrate Was illustrated in FIGS. 6A and 6B. As illustrated in FIG. 7, the film M may be partially formed at a predetermined position in the surface of the substrate W. Further, as illustrated in FIG. 8, it is possible to adjust an in-surface embedding amount of the film M of the substrate W having a groove, to suppress a void or a seam in the groove.

In the present exemplary embodiment, the plasma film forming apparatus 1 has the first moving mechanism 17 that moves the second nozzle 15 on the substrate W in the substrate support 11, and the second moving mechanism 18 that moves the substrate support 11, and thus the second nozzle 15 and the substrate support 11 can be moved relatively to each other by a relatively simple mechanism.

### Second Exemplary Embodiment

In one embodiment, the plasma film forming apparatus 1 may be configured such that the first nozzle 14 has a plurality of ejection ports 14a.

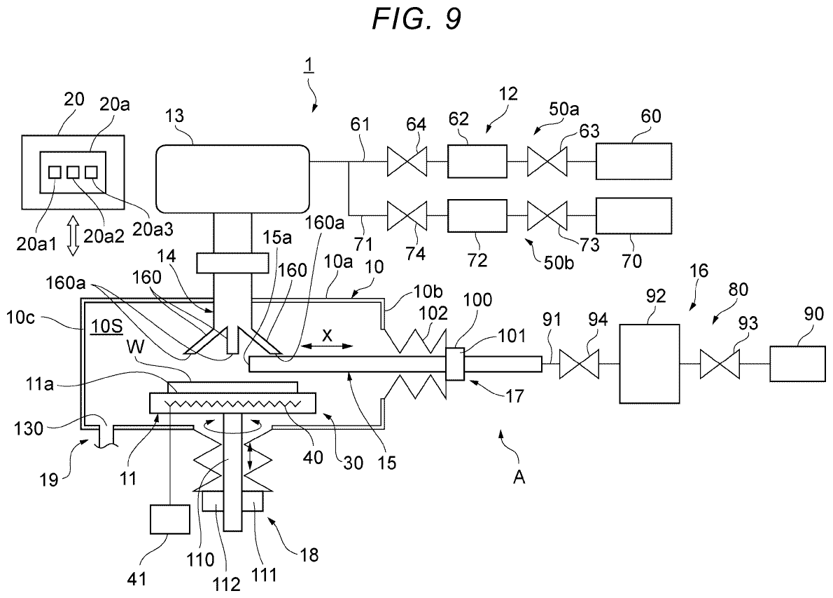

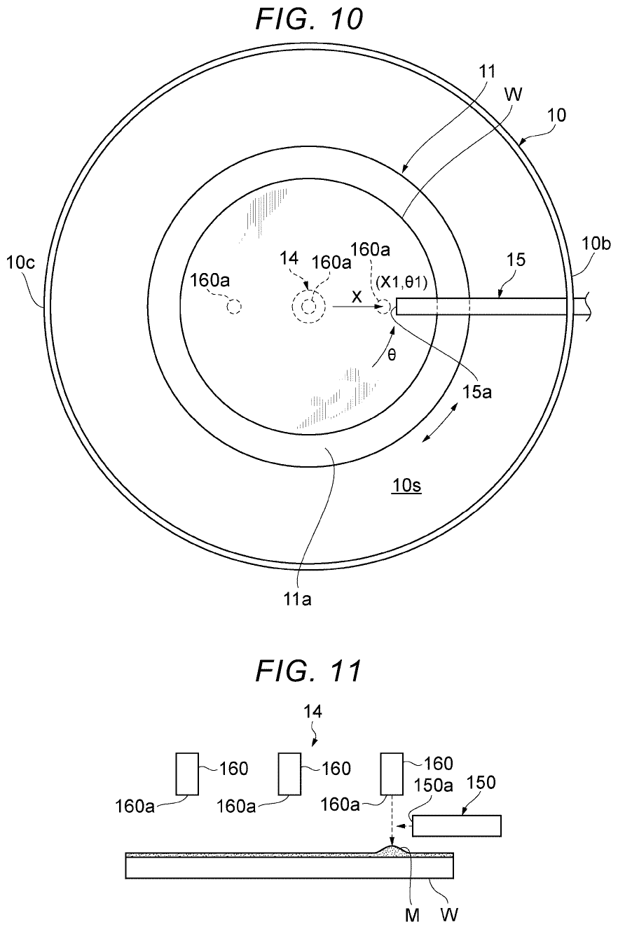

As illustrated in FIG. 9, in one embodiment, the first nozzle 14 has a plurality of branches 160 that branch in the chamber 10. Each of the branches 160 has an ejection port 160a at a distal end thereof. In one embodiment, a plurality of ejection ports 160a are disposed in an unbiased manner in the surface of the substrate W on the substrate support 11. As an example, as illustrated in FIG. 10, the plurality of ejection ports 160a are disposed to be arranged in the horizontal direction X at a plurality of locations on the diameter of the substrate W. For example, the plurality of ejection ports 160a are disposed above a central portion of the substrate W and above an intermediate portion between the central portion and an outer peripheral portion on both sides interposing the central portion. The disposition and the number of the plurality of ejection ports 160a are not limited thereto, and may be arbitrarily selected. Other configurations may be the same as those of the plasma film forming apparatus 1 according to the first exemplary embodiment.

As one embodiment, when the relative position between the second nozzle 15 and the substrate support 11 is adjusted (step S2) or changed (step S4), the ejection port 15a of the second nozzle 15 is moved to the vicinity immediately below the ejection port 160a of any one of the branches 160 of the first nozzle 14 by the first moving mechanism 17. The ejection port 15a of the second nozzle 15 moves to the vicinity of the ejection port 160a of the branch 160 close to the target position (x1) in the horizontal direction X of the substrate W. Further, the substrate support 11 is rotated by the second moving mechanism 18, and the target position (θ1) of the substrate W in the circumferential direction 0 is moved below the ejection port 160a of the branch 160 and the ejection port 15a of the second nozzle 15. As a result, the ejection port 160a of the branch 160 and the ejection port 15a of the second nozzle 15 are located above the target position (x1, θ1) on the substrate W. Then, as illustrated in FIG. 11, the first gas is supplied from the ejection port 14a of the first nozzle 14 to the substrate W, and the second gas is supplied from the ejection port 15a of the second nozzle 15 to the first gas. Accordingly, the second gas reacts with the first gas immediately above the substrate W, and the film M is formed at the target position (x1, θ1) of the substrate W immediately below thereof. Thereafter, the supply of the first gas and the second gas is stopped.

According to the present exemplary embodiment, the second gas may be ejected and caused to react with the first gas in a state where the ejection port 15a of the second nozzle 15 is brought close to the ejection port 160a of the branch 160. As a result, the reaction between the first gas and the second gas is efficiently performed, and the film can be appropriately formed at the desired position on the substrate W. As a result, the in-surface distribution of the thickness of the film on the substrate W can be accurately controlled.

### Third Exemplary Embodiment

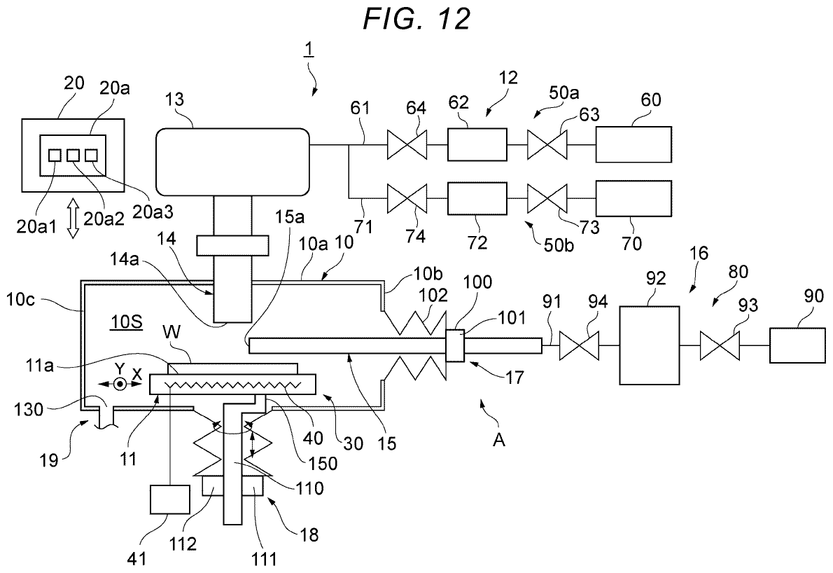

As one embodiment, the second moving mechanism 18 may have a function of moving the substrate support 11 with respect to the second nozzle 15 in two horizontal directions (X-Y directions) orthogonal to each other. In one embodiment, as illustrated in FIG. 12, the second moving mechanism 18 includes a driver 150 that moves the substrate support 11 in the X direction and the Y direction. The driver 150 includes, but is not particularly limited to, an X-Y stage in which driving in the X direction and driving in the Y direction are integrated. Other configurations may be the same as those of the plasma film forming apparatus 1 according to the first exemplary embodiment.

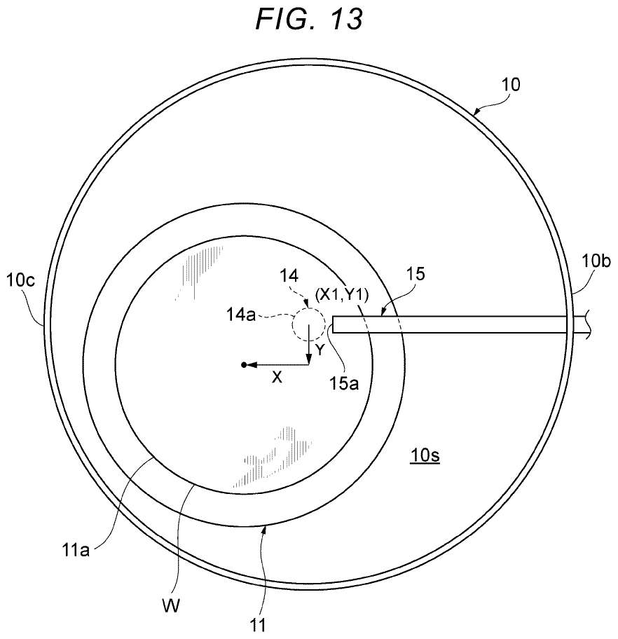

As one embodiment, when the relative position between the second nozzle 15 and the substrate support 11 is adjusted (step S2) or changed (step S4), the ejection port 15a of the second nozzle 15 is maintained at a position immediately below the first nozzle 14. Then, as illustrated in FIG. 13, the substrate support 11 is moved in the X direction and the Y direction by the second moving mechanism 18, and a target position (x1, y1) on the substrate W is moved below the ejection port 15a of the second nozzle 15 and the ejection port 14a of the first nozzle 14. Then, the first gas is supplied from the ejection port 14a of the first nozzle 14 to the substrate W, and the second gas is supplied from the ejection port 15a of the second nozzle 15 to the first gas. Accordingly, the second gas reacts with the first gas immediately above the substrate W, and the film is formed at the target position (x1, y1) of the substrate W immediately below thereof. Thereafter, the supply of the first gas and the second gas is stopped.

According to the present exemplary embodiment, the film can be formed on the substrate W while maintaining a state where the ejection port 15a of the second nozzle 15 is brought close to the ejection port 14a of the first nozzle 14. As a result, the reaction between the first gas and the second gas is efficiently performed, and the film can be appropriately formed at the desired position on the substrate W. As a result, the in-surface distribution of the thickness of the film on the substrate W can be accurately controlled.

The mover A is not limited to the mover A according to the first to third exemplary embodiments. The mover A need only be able to move the second nozzle 15 relatively to the substrate support 11 and to change the position at which the film M is formed on the substrate W on the substrate support 11 to an optional position in the substrate surface, and the mover A may move only the second nozzle 15, move only the substrate support 11, or move both the second nozzle 15 and the substrate support 11. When only the second nozzle 15 is moved, the first moving mechanism 17 may move the second nozzle 15 in the X direction and the Y direction.

### Fourth Exemplary Embodiment

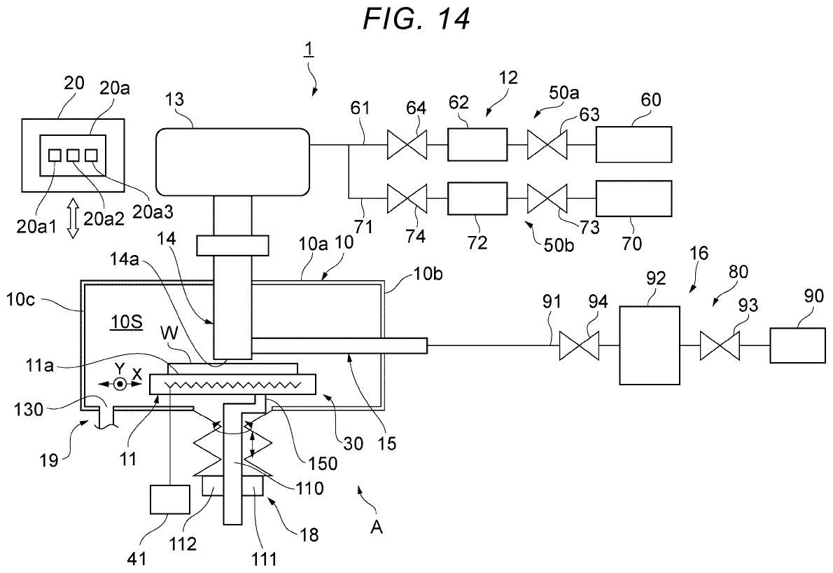

In one embodiment, the plasma film forming apparatus 1 may have a configuration in which the second nozzle 15 is connected to the vicinity of the distal end of the first nozzle 14, as illustrated in FIG. 14.

The second nozzle 15 is connected to the distal end of the first nozzle 14 immediately before the ejection port 14a, and configured to combine the second gas with the first gas in the first nozzle 14.

In one embodiment, the second moving mechanism 18 includes the driver 150 that moves the substrate support 11 in the X direction and the Y direction. The driver 150 includes, but is not particularly limited to, an X-Y stage in which driving in the X direction and driving in the Y direction are integrated.

In one embodiment, the first moving mechanism 17 is not needed, and the second nozzle 15 may be fixed to the side wall 10b of the chamber 10. Other configurations may be the same as those of the plasma film forming apparatus 1 according to the first exemplary embodiment.

As one embodiment, when the relative position between the second nozzle 15 and the substrate support 11 is adjusted (step S2) or changed (step S4), the substrate support 11 is moved in the X direction and the Y direction by the second moving mechanism 18, and the target position (x1, y1) on the substrate W is moved below the ejection port 14a of the first nozzle 14. Then, the first gas is supplied from the ejection port 14a of the first nozzle 14 to the substrate W, and the second gas is supplied from the second nozzle 15 into the first nozzle 14. The first gas and the second gas react with each other in the first nozzle 14 or immediately above the substrate W, and the film is formed at the target position (x1, y1) of the substrate W immediately below thereof. Thereafter, the supply of the first gas and the second gas is stopped.

According to the present exemplary embodiment, the second gas reacts with the first gas in the first nozzle 14, so that the reaction between the first gas and the second gas is efficiently performed, and the film can be appropriately formed at the desired position on the substrate W. As a result, the in-surface distribution of the thickness of the film on the substrate W can be accurately controlled.

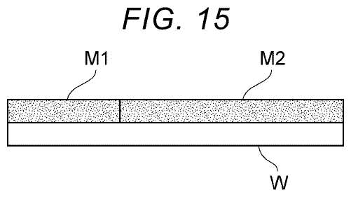

In the first to fourth exemplary embodiments, the film formation with the same film quality and the same film type are performed in the substrate surface, but the film formation with different film qualities and different film types may be performed in the substrate surface. In one embodiment, the second gas supply 16 may be configured to selectively supply a plurality of types of second gas, and the first gas supply 12 may be configured to selectively supply a plurality of types of first gas. As an example, when the relative position between the second nozzle 15 and the substrate support 11 is changed and the forming position on the substrate W is changed (step S4), the type of the second gas supplied from the second nozzle 15 or the type of the first gas supplied from the first nozzle 14 is changed. As a result, films having different film qualities and different film types are formed at different forming positions on the substrate W. As an example, as illustrated in FIG. 15, different types of films M1 and M2 are formed on the substrate W.

### EMBODIMENTS OF THE PRESENT DISCLOSURE FURTHER INCLUDE THE FOLLOWING ASPECTS

### (Appendix 1)

A plasma film forming apparatus including: a chamber; a substrate support configured to support a substrate in the chamber; a first nozzle configured to supply first gas that is formed into plasma to a region on the substrate support; a second nozzle configured to supply second gas that reacts with the first gas into the chamber, in which the first gas reacts with the second gas in the chamber to form a film at a predetermined position on the substrate supported by the substrate support; and a mover configured to move the second nozzle relatively to the substrate support, in which the predetermined position is determined based on a position of the second nozzle relative to the substrate support.

### (Appendix 2)

The plasma film forming apparatus according to Appendix 1, in which the mover has a moving mechanism configured to move the second nozzle above the substrate support.

### (Appendix 3)

The plasma film forming apparatus according to Appendix 2, in which the first nozzle has a plurality of ejection ports for ejecting the first gas toward the region on the substrate support, and the mover is configured to move the second nozzle to move the ejection ports of the second nozzle to a position at which ejection of the second gas to the first gas ejected from each ejection port of the first nozzle toward the region on the substrate support is enabled.

### (Appendix 4)

A plasma film forming apparatus including: a chamber; a substrate support configured to support a substrate in the chamber; a first nozzle configured to supply first gas that is formed into plasma to a region on the substrate support; a second nozzle configured to supply second gas that reacts with the first gas into the first nozzle, in which the first gas reacts with the second gas to form a film at a predetermined position on the substrate supported by the substrate support; and a mover configured to relatively move the first nozzle and the substrate support, in which the predetermined position is determined based on a position of the first nozzle relative to the substrate support.

### (Appendix 5)

The plasma film forming apparatus according to any one of Appendices 1 to 4, in which the mover has a moving mechanism configured to move the substrate support.

### (Appendix 6)

The plasma film forming apparatus according to any one of Appendices 1 to 5, in which the film formed on the substrate is in a liquid state.

### (Appendix 7)

A plasma film forming method executed in a plasma film forming apparatus including a chamber, a substrate support configured to support a substrate in the chamber, a first nozzle configured to supply gas to a region on the substrate support, and a second nozzle configured to supply gas into the chamber, the plasma film forming method including: (a) preparing the substrate on the substrate support; (b) adjusting a relative position between the second nozzle and the substrate support; (c) supplying, via the first nozzle, first gas that is formed into plasma to the substrate; and (d) supplying, via the second nozzle, second gas that reacts with the first gas into the chamber, in which the first gas reacts with the second gas in the chamber to form a film at a predetermined position on the substrate, in which the (b) includes adjusting the relative position between the second nozzle and the substrate support to determine the predetermined position.

### (Appendix 8)

The plasma film forming method according to Appendix 7, in which the first nozzle has a plurality of ejection ports for ejecting the first gas toward the region on the substrate support, the second nozzle has an ejection port for ejecting the second gas, and in the (b), the second nozzle is moved to move the ejection port of the second nozzle to a position at which ejection of the second gas to the first gas ejected from the ejection port in any one ejection port among the plurality of ejection ports of the first nozzle toward the region on the substrate support is enabled, the first gas reacts with the second gas above the substrate, and a reaction product of the first gas and the second gas is deposited on the substrate to form the film on the substrate.

### (Appendix 9)

A plasma film forming method executed in a plasma film forming apparatus including a chamber, a substrate support configured to support a substrate in the chamber, a first nozzle configured to supply gas to a region on the substrate support, and a second nozzle configured to supply gas into the first nozzle, the plasma film forming method including: (a) preparing the substrate on the substrate support; (b) adjusting a relative position between the first nozzle and the substrate support; (c) supplying, via the first nozzle, first gas that is formed into plasma to the substrate; and (d) supplying, via the second nozzle, second gas that reacts with the first gas into the first nozzle, in which the first gas reacts with the second gas to form a film at a predetermined position on the substrate, in which the (b) includes adjusting the relative position between the first nozzle and the substrate support to determine the predetermined position.

### (Appendix 10)

The plasma film forming method according to any one of Appendices 7 to 9, further including: (e) supplying the first gas from the first nozzle to the region on the substrate support to post-process the film formed on the substrate.

### (Appendix 11)

The plasma film forming method according to any one of Appendices 7 to 10, in which in the (d), a liquid-state film is formed on the substrate.

The respective embodiments described above have been described for illustration, and are not intended to limit the scope of the present disclosure. Various modifications may be made to the respective embodiments of the present disclosure without departing from the scope and gist of the present disclosure. For example, some components in one embodiment may be added to another embodiment. Some components in an embodiment may be replaced with corresponding components in another embodiment.

According to one exemplary embodiment of the present disclosure, a technique for performing the local film formation on the substrate by using the plasma can be provided.

1. A plasma film forming apparatus comprising:
a chamber;
a substrate support configured to support a substrate in the chamber;
a first nozzle configured to supply first gas that is formed into plasma to a region on the substrate support;
a second nozzle configured to supply second gas that reacts with the first gas into the chamber, in which the first gas reacts with the second gas in the chamber to form a film at a predetermined position on the substrate supported by the substrate support; and
a mover configured to move the second nozzle relatively to the substrate support, in which the predetermined position is determined based on a position of the second nozzle relative to the substrate support.

2. The plasma film forming apparatus according to claim 1, wherein
the mover has a moving mechanism configured to move the second nozzle above the substrate support.

3. The plasma film forming apparatus according to claim 2, wherein
the first nozzle has a plurality of ejection ports for ejecting the first gas toward the region on the substrate support, and
the mover is configured to move the second nozzle to move the ejection ports of the second nozzle to a position at which ejection of the second gas to the first gas ejected from each ejection port of the first nozzle toward the region on the substrate support is enabled.

4. A plasma film forming apparatus comprising:
a chamber;
a substrate support configured to support a substrate in the chamber;
a first nozzle configured to supply first gas that is formed into plasma to a region on the substrate support;
a second nozzle configured to supply second gas that reacts with the first gas into the first nozzle, in which the first gas reacts with the second gas to form a film at a predetermined position on the substrate supported by the substrate support; and
a mover configured to relatively move the first nozzle and the substrate support, in which the predetermined position is determined based on a position of the first nozzle relative to the substrate support.

5. The plasma film forming apparatus according to claim 1, wherein
the mover has a moving mechanism configured to move the substrate support.

6. The plasma film forming apparatus according to claim 1, wherein
the film formed on the substrate is in a liquid state.

7. A plasma film forming method executed in a plasma film forming apparatus including
a chamber,
a substrate support configured to support a substrate in the chamber,
a first nozzle configured to supply gas to a region on the substrate support, and
a second nozzle configured to supply gas into the chamber,
the plasma film forming method comprising:
(a) preparing the substrate on the substrate support;
(b) adjusting a relative position between the second nozzle and the substrate support;
(c) supplying, via the first nozzle, first gas that is formed into plasma to the substrate; and
(d) supplying, via the second nozzle, second gas that reacts with the first gas into the chamber, in which the first gas reacts with the second gas in the chamber to form a film at a predetermined position on the substrate, wherein
the (b) includes adjusting the relative position between the second nozzle and the substrate support to determine the predetermined position.

8. The plasma film forming method according to claim 7, wherein
the first nozzle has a plurality of ejection ports for ejecting the first gas toward the region on the substrate support,
the second nozzle has an ejection port for ejecting the second gas, and
in the (b), the second nozzle is moved to move the ejection port of the second nozzle to a position at which ejection of the second gas to the first gas ejected from the ejection port in any one ejection port among the plurality of ejection ports of the first nozzle toward the region on the substrate support is enabled, the first gas reacts with the second gas above the substrate, and a reaction product of the first gas and the second gas is deposited on the substrate to form the film on the substrate.

9. A plasma film forming method executed in a plasma film forming apparatus including
a chamber,
a substrate support configured to support a substrate in the chamber,
a first nozzle configured to supply gas to a region on the substrate support, and
a second nozzle configured to supply gas into the first nozzle,
the plasma film forming method comprising:
(a) preparing the substrate on the substrate support;
(b) adjusting a relative position between the first nozzle and the substrate support;
(c) supplying, via the first nozzle, first gas that is formed into plasma to the substrate; and
(d) supplying, via the second nozzle, second gas that reacts with the first gas into the first nozzle, in which the first gas reacts with the second gas to form a film at a predetermined position on the substrate, wherein
the (b) includes adjusting the relative position between the first nozzle and the substrate support to determine the predetermined position.

10. The plasma film forming method according to claim 7, further comprising:
(e) supplying the first gas from the first nozzle to the region on the substrate support to post-process the film formed on the substrate.

11. The plasma film forming method according to claim 7, wherein
in the (d), a liquid-state film is formed on the substrate.

12. The plasma film forming method according to claim 9, further comprising:
(e) supplying the first gas from the first nozzle to the region on the substrate support to post-process the film formed on the substrate.

13. The plasma film forming method according to claim 9, wherein
in the (d), a liquid-state film is formed on the substrate.
